(19) United States
(12) Patent Application Publication
(10) Pub. No.: US 2012/0199386 A1
(43) Pub. Date: Aug. 9, 2012

(54) MULTILAYER PRINTED WIRING BOARD

(75) Inventors: Takema Adachi, Ogaki-shi (JP); Liyi Chen, Ogaki-shi (JP)

(73) Assignee: IBIDEN CO., LTD., Ogaki-shi (JP)

(21) Appl. No.: 13/325,414

(22) Filed: Dec. 14, 2011

Related U.S. Application Data
(60) Provisional application No. 61/439,640, filed on Feb. 4, 2011.

(51) Int. Cl. H05K 1/02; H05K 3/02

(52) U.S. Cl. 174/258; 427/96.9

(57) ABSTRACT

A printed wiring board including a core substrate having a metal layer, a first resin insulation layer on a surface of the metal layer and a second resin insulation layer on the opposite surface of the metal layer, a first conductive circuit formed on the first layer, a second conductive circuit formed on the second layer, and a through-hole conductor formed in a penetrating hole through the substrate and connecting the first and second circuits. The metal layer has an opening filled with a filler resin, the penetrating hole has a first opening in the first layer, a second opening in the second layer and a third opening in the filler resin, the first opening tapers toward the filler resin, the second opening tapers toward the filler resin, and the third opening is connecting the first and second openings.

### CROSS-REFERENCE TO RELATED APPLICATIONS

The present application is based on and claims the benefit of priority to U.S. Application No. 61/439,640, filed Feb. 4, 2011, the entire contents of which are incorporated herein by reference.

### BACKGROUND OF THE INVENTION

1. Field of the Invention

The present invention relates to a printed wiring board which has a core substrate having a metal layer and resin insulation layers sandwiching the metal layer, conductive circuits formed on upper and lower surfaces of the core substrate, and a through-hole conductor penetrating through the core substrate and connecting the conductive circuits on the upper and lower surfaces of the core substrate. The present invention also relates to a method for manufacturing such a printed wiring board.

2. Discussion of the Background

Japanese Laid-Open Patent Publication No. 2003-304063 describes a method for manufacturing a metallic core substrate. The manufacturing method includes a step to form a penetrating hole in a metal layer, a step to laminate insulation layers on upper and lower surfaces of the metal layer, a step to form a through hole that goes through the penetrating hole in the metal layer and penetrates through the insulation layers formed on the upper and lower surfaces of the metal layer, and a step to form a conductive layer (through-hole conductor) on the inner wall of the through hole. The contents of this publication are incorporated herein by reference in their entirety.

### SUMMARY OF THE INVENTION

According to one aspect of the present invention, a printed wiring board includes a core substrate having a metal layer, a first resin insulation layer formed on a first surface of the metal layer and a second resin insulation layer formed on a second surface of the metal layer on the opposite side of the first surface of the metal layer, a first conductive circuit formed on a surface of the first resin insulation layer of the core substrate, a second conductive circuit formed on a surface of the second resin insulation layer of the core substrate, and a through-hole conductor formed in a penetrating hole penetrating through the core substrate and connecting the first conductive circuit and the second conductive circuit. The metal layer has an opening portion filled with a tiller resin, the penetrating hole formed through the core substrate has a first opening portion formed in the first resin insulation layer, a second opening portion formed in the second resin insulation layer and a third opening portion formed in the filler resin, the first opening portion becomes narrower from the surface of the first resin insulation layer toward the filler resin, the second opening portion becomes narrower from the surface of the second resin insulation layer toward the filler resin, and the third opening portion is connecting the first opening portion and the second opening portion.

According to another aspect of the present invention, a method for manufacturing a printed wiring board including preparing a core substrate having a metal layer, a first resin insulation layer formed on a first surface of the metal layer and a second resin insulation layer formed on a second surface of the metal layer on the opposite side of the first surface of the metal layer, forming a first conductive circuit on a surface of the first resin insulation layer of the core substrate, forming a second conductive circuit on a surface of the second resin insulation layer of the core substrate, and forming a through-hole conductor in a penetrating hole penetrating through the core substrate and connecting the first conductive circuit and the second conductive circuit. The preparing of the core substrate includes filling an opening portion of the metal layer with a filler resin, forming a penetrating hole through the core substrate such that a first opening portion is formed in the first resin insulation layer, a second opening portion is formed in the second resin insulation layer and a third opening portion is formed in the filler resin, and the forming of the penetrating hole includes forming the first opening portion such that the first opening portion becomes narrower from the surface of the first resin insulation layer toward the filler resin, forming the second opening portion such that the second opening portion becomes narrower from the surface of the second resin insulation layer toward the filler resin, and forming the third opening portion such that the third opening portion is connecting the first opening portion and the second opening portion.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIGS. 1(A)-(F) are views of steps showing a method for manufacturing a multilayer printed wiring board according to an embodiment of the present invention;

FIGS. 2(A)-(D) are views of steps showing a method for manufacturing a multilayer printed wiring board according to the embodiment;

FIGS. 3(A)-(D) are views of steps showing a method for manufacturing a multilayer printed wiring board according to the embodiment;

FIGS. 4(A)-(C) are views of steps showing a method for manufacturing a multilayer printed wiring board according to the embodiment;

FIGS. 5(A)-(B) are views of steps showing a method for manufacturing a multilayer printed wiring board according to the embodiment;

FIG. 6 is a cross-sectional view of a multilayer printed wiring board according to the embodiment;

FIG. 7 is a cross-sectional view showing a state in which an IC chip is mounted on the multilayer printed wiring board shown in FIG. 6;

FIGS. 8(A)-(B) are views showing an example of each measurement of a core substrate;

FIGS. 9(A)-(D) are views showing examples of the shape of a penetrating hole for a through-hole conductor;

FIG. 10 is a view showing the shape of a drill;

FIG. 11(A) shows the opening of a first opening portion, and FIG. 11(B) shows the opening of a second opening portion;

FIG. 12(A) shows a penetrating hole that does not have a third opening portion, FIG. 12(B) shows a through-hole conductor formed in the penetrating hole shown in FIG. 12(A), and FIG. 12(C) shows an example of a penetrating hole in the embodiment of the present invention;

FIGS. 13(A)-(D) are views showing inner walls of penetrating holes for through-hole conductors and distances between the walls;

FIGS. 14(A)-(D) are views of steps showing a method for manufacturing a printed wiring board according to a modified example of the embodiment; and

FIGS. 15(A)-(C) are views of steps showing a method for manufacturing a printed wiring board according to the modified example of the embodiment.

### DETAILED DESCRIPTION OF THE EMBODIMENTS

The embodiments will now be described with reference to the accompanying drawings, wherein like reference numerals designate corresponding or identical elements throughout the various drawings.

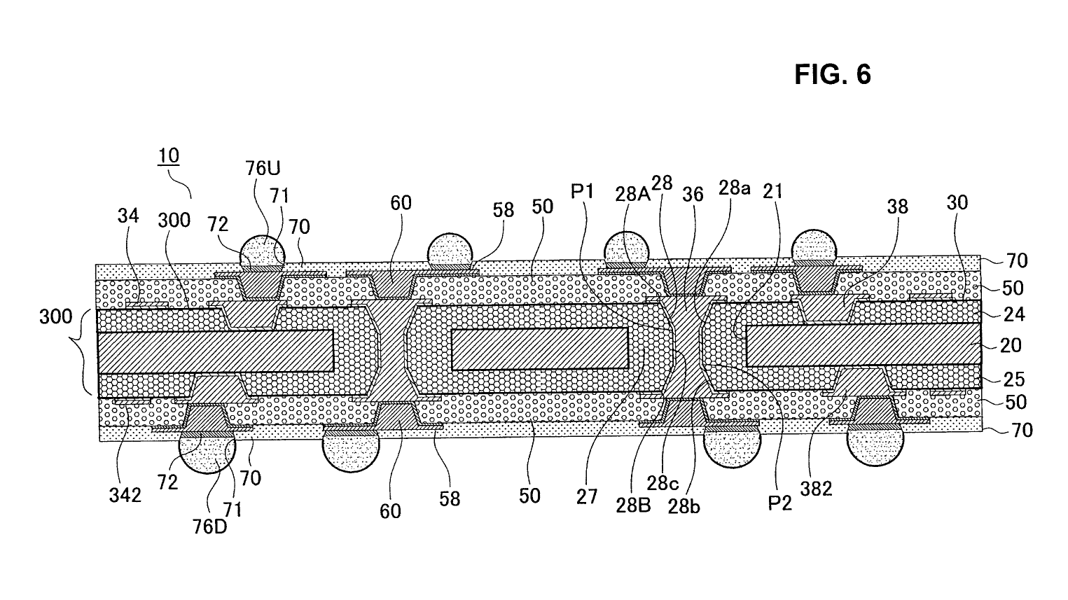

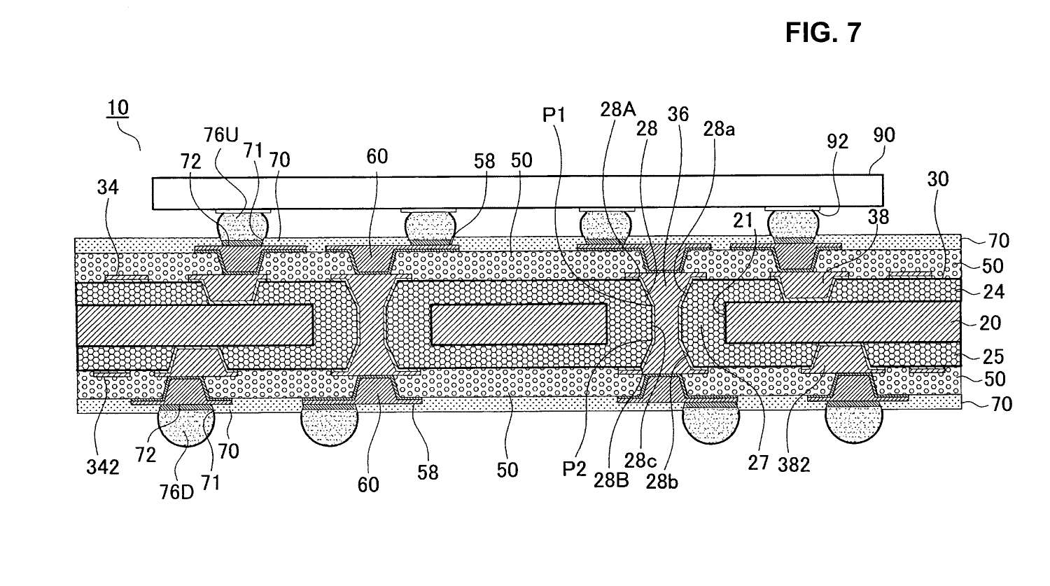

FIGS. 6 and 7 show a cross-sectional view of a multilayer printed wiring board according to an embodiment of the present invention. Multilayer printed wiring board 10 shown in FIG. 6 has printed wiring board 30 and buildup layers laminated thereon. FIG. 7 shows a state in which IC chip 90 is mounted on multilayer printed wiring board 10 shown in FIG. 6. IC chip 90 is mounted on multilayer printed wiring board 10 via solder bumps (76U). Multilayer printed wiring board 10 has printed wiring board 30, interlayer resin insulation layers 50 formed on both surfaces of the printed wiring board, conductive circuits 58 on the interlayer resin insulation layers, and via conductors 60 that connect the conductive circuits of the printed wiring board and the conductive circuits on the interlayer resin insulation layers.

Multilayer printed wiring board 10 has core substrate 300 that has a first surface and a second surface opposite the first surface, conductive circuits (34, 342) on the core substrate, and buildup layers. Printed wiring board 30 is formed with core substrate 300 and conductive circuits (34, 342). Core substrate 300 has metal layer 20 which has opening 21 and a first surface and a second surface opposite the first surface, filler resin 27 filling the opening in metal layer 20, first resin insulation layer 24 formed on the first surface of the metal layer, second resin insulation layer 25 formed on the second surface of the metal layer, and through-hole conductor 36 formed in penetrating hole 28 for a through-hole conductor that penetrates through the first resin insulation layer, the filler resin and the second resin insulation layer. Metal layer 20 is sandwiched by first resin insulation layer 24, which has an upper surface and a lower surface opposite the upper surface, and by second resin insulation layer 25, which has a main surface and a secondary surface opposite the main surface. The first surface of the metal layer faces the lower surface of the first resin insulation layer. The second surface of the metal layer faces the secondary surface of the second resin insulation layer. First conductive circuit 34 is formed on the upper surface of the first resin insulation layer. Second conductive circuit 342 is formed on the main surface of the second resin insulation layer. A first conductive circuit and a second conductive circuit of printed wiring board 30 are connected by through-hole conductor 36. The first surface of the core substrate corresponds to the upper surface of the first resin insulation layer, and the second surface of the core substrate corresponds to the main surface of the second resin insulation layer.

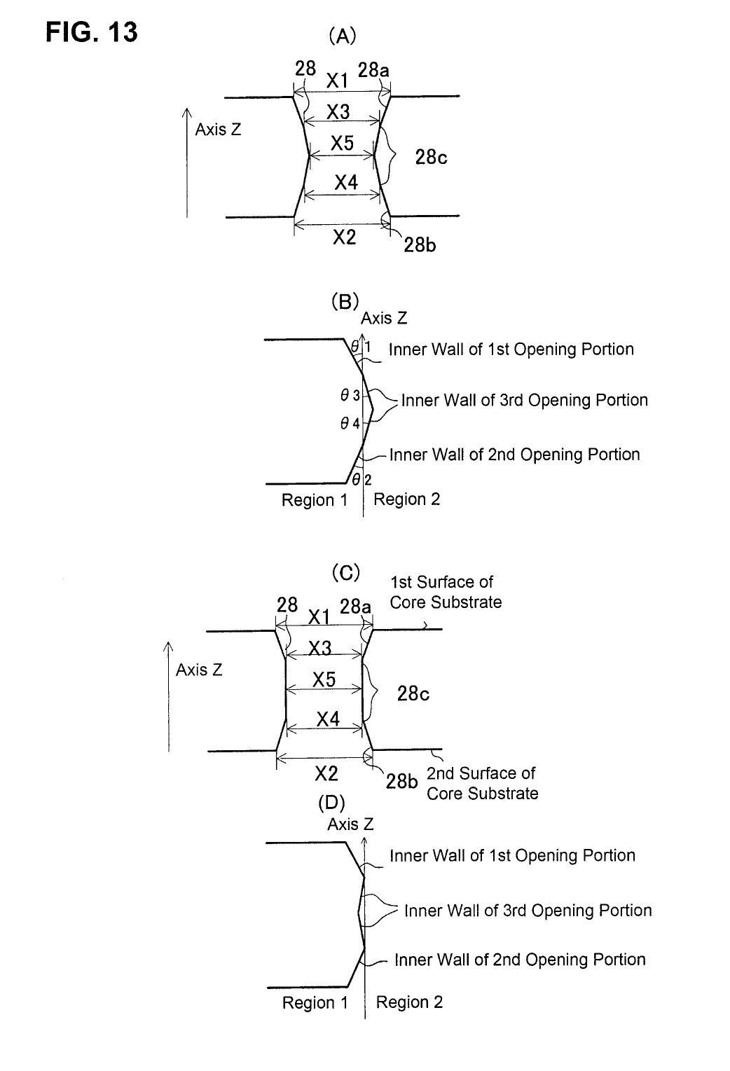

Penetrating hole 28 is formed with first opening portion (28a) formed in the first resin insulation layer, second opening portion (28b) formed in the second resin insulation layer, and third opening portion (28c) formed in the filler resin. The first opening portion and the second opening portion are connected by the third opening portion. The first opening portion has first opening (28A) on the first surface of the core substrate and gradually becomes narrower from the first surface of the core substrate toward the filler resin. The second opening portion has second opening (28B) on the second surface of the core substrate and becomes narrower from the second surface of the core substrate toward the filler resin. The third opening portion has a third opening at the boundary of the first opening portion and the third opening portion, and has a fourth opening at the boundary of the second opening portion and the third opening portion. The diameter of the third opening portion is substantially the same from the boundary of the first opening portion and the third opening portion to the boundary of the second opening portion and the third opening portion. Therefore, penetrating hole 28 becomes gradually narrower from the first surface of the core substrate toward the boundary of the first opening portion and the third opening portion, and at the boundary of the first opening portion and the third opening portion the inner wall of the penetrating hole bends in the direction of the cross section of the core substrate. In addition, penetrating hole 28 becomes gradually narrower from the second surface of the core substrate toward the boundary of the second opening portion and the third opening portion, and at the boundary of the second opening portion and the third opening portion, the inner wall of the penetrating hole bends in the direction of the cross section of the core substrate. To bend in the direction of the cross section means for the inner wall of a penetrating hole to become closer to being parallel to axis Z (the axis perpendicular to the first surface of the core substrate). The situation is shown in FIG. 13(B). Angle (θ1) between axis Z and the inner wall of the first opening portion is greater than angle (θ3) between axis Z and the inner wall of the third opening portion. Angle (θ2) between axis Z and the inner wall of the second opening portion is greater than angle (θ4) between axis Z and the inner wall of the third opening portion. FIGS. 13(A), (B) and (C) show preferred shapes of the penetrating hole. In preferred examples, the inner wall of the first opening portion and the inner wall of the third opening portion are present in different regions bordered by axis Z which passes through the boundary of the first opening portion and the third opening portion (FIGS. 13(A) and (B)). Alternatively, the inner wall of the third opening portion corresponds to axis Z (FIG. 13(C)). In examples shown in FIGS. 13(A) and (B), the inner wall of the first opening portion is present in region 1, and the inner wall of the third opening portion is present in region 2. In the example shown in FIG. 13(C), the inner wall of the first opening portion is present in region 1, and the inner wall of the third opening portion corresponds to axis Z. The inner wall of the second opening portion and the inner wall of the third opening portion are present in different regions bordered by axis Z which passes through the boundary of the second opening portion and the third opening portion (FIGS. 13(A) and (B)). Alternatively, the inner wall of the third opening portion corresponds to axis Z (FIG. 13(C)). In examples shown in FIGS. 13(A) and (B), the inner wall of the second opening portion is present in region 1, and the inner wall of the third opening portion is present in region 2. In the example shown in FIG. 13(C), the inner wall of the second opening portion is present in region 1, and the inner wall of the third opening portion corresponds to axis Z. Region 2 is positioned on the penetrating-hole side, and region 1 is positioned on the substrate side. Region 1 is the region opposite region 2. FIG. 13(D) shows a shape that is not preferred for a penetrating hole. In FIG. 13(D), the inner wall of a penetrating hole bends at the boundary of a first opening portion and a third opening portion as well as at the boundary of a second opening portion and the third opening portion. By connecting a first opening portion and a second opening portion by a third opening portion, a penetrating hole made up of the first opening portion, second opening portion and third opening portion is formed in the core substrate. When the diameter of the first opening is referred to as (X1), the diameter of the second opening as (X2), the diameter of the third opening as (X3), the diameter of fourth opening as (X4), and the diameter of the narrowest portion of the third opening portion between the boundary of the first opening portion and the third opening portion and the boundary of the second opening portion and the third opening portion is referred to as (X5), a penetrating hole in the embodiment satisfies the following relationship (1). FIGS. 13(A) and (C) show (X1, X2, X3, X4, X5). FIG. 13(A) shows an example in which the third opening portion has its narrowest portion between the boundary of the first opening portion and the third opening portion and the boundary of the second opening portion and the third opening portion. FIG. 13(C) shows an example in which the third opening portion is shaped to be straight. In FIG. 13(C), (X3), (X4) and (X5) are equal.

relationship (1): X3/X1 is smaller than X5/X3, and X4/X2 is smaller than X5/X4.

A penetrating hole may satisfy the following relationship (2) in addition to relationship (1).

relationship (2): X5/X3 and X5/X4 are in the range of 0.7 to 1.0.

From the viewpoint of reliability of a through-hole conductor, relationship (2) is preferred to be set in the range of 0.8 to 1.0. When the third opening portion satisfies relationship (2), the diameter of the third opening portion is substantially the same between the boundary of the first opening portion and the third opening portion and the boundary of the second opening portion and the third opening portion.

FIGS. 13(A) and (C) show examples of how to measure (X1, X2, X3, X4, X5). FIGS. 13(A) and (C) are cross-sectional views obtained by slicing a penetrating hole by a plane that passes through the gravity center of first opening (28A) and is perpendicular to the first surface of the core substrate. The values of (X1, X2, X3, X4, X5) are those measured in cross-sectional views shown in FIGS. 13(A) and (C). The distance between the inner walls facing each other on the first surface of the core substrate is (X1). The distance between the inner walls facing each other on the second surface of the core substrate is (X2). The distance between the inner walls facing each other at the boundary of the first opening portion and the third opening portion is (X3). The distance between the inner walls facing each other at the boundary of the second opening portion and the fourth opening portion is (X4). In the cross-sectional views shown in FIGS. 13(A) and (C), (X5) is the smallest distance between the inner walls of the third opening portion. A through-hole conductor is preferred to be formed by filling with plating the above-described penetrating hole for a through-hole conductor.

As shown in FIG. 6, the core substrate may also have via conductor 38 which penetrates through first resin insulation layer 24 and connects metal layer 20 and conductive circuit 34. Moreover, the core substrate may also have via conductor 382 which penetrates through second resin insulation layer 24 and connects metal layer 20 and conductive circuit 342. It is an option for the core substrate not to have via conductors (38, 382).

A through-hole conductor according to the embodiment has a narrow diameter in the portion that passes through the metal layer. Thus, the volume of the metal layer is set greater. Accordingly, the printed wiring board according to the embodiment has excellent heat radiation. With excellent heat radiation, the amount of expansion caused by heat decreases, suppressing the through-hole conductor from being deformed. Therefore, even though a through-hole conductor in the printed wiring board according to the embodiment has a narrow portion or a bent portion, cracking seldom occurs in the through-hole conductor. Also, cracking originating in the bent portion seldom occurs. According to the printed wiring board of the embodiment, the diameter of a penetrating hole for a through-hole conductor is greater at an end portion of the penetrating hole, and narrower at the central portion of the core substrate. Therefore, it is easy to fill a penetrating hole with plating, and a void or the like seldom remains in the through-hole conductor. From those points of view as well, the reliability of a through-hole conductor of the embodiment is enhanced.

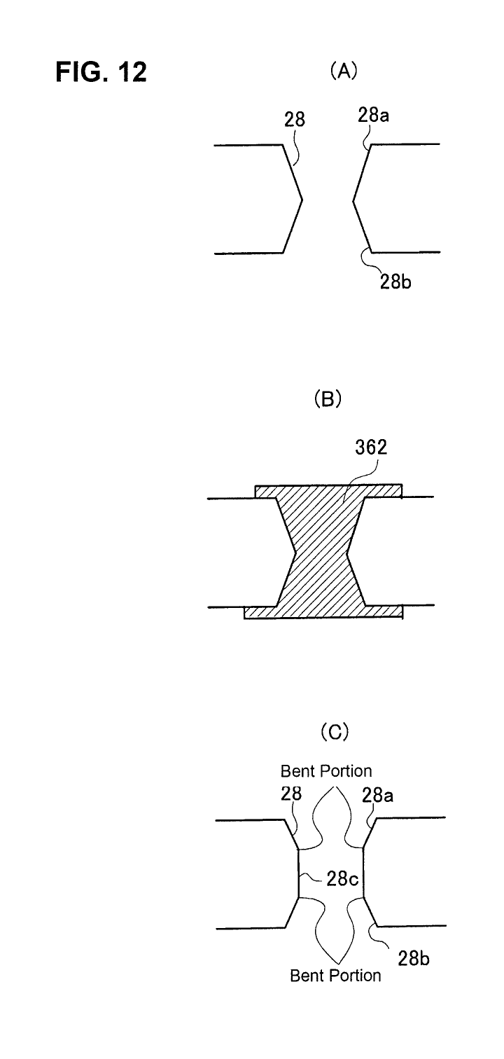

When a penetrating hole for a through-hole conductor is made up of a first opening portion and a second opening portion (when the penetrating hole does not have a third opening portion), the bent portion of the penetrating hole is the portion where the first opening portion and the second opening portion are connected (FIG. 12(A)). When stress is exerted on a through-hole conductor (FIG. 12(B)) formed in the penetrating hole shown in FIG. 12(A), the stress concentrates in the connection portion which is the narrowest portion. Therefore, in the through-hole conductor shown in FIG. 12(B), cracking originates in the connection portion. By contrast, a through-hole conductor according to the embodiment is formed in a penetrating hole made up of a first opening portion, a second opening portion and a third opening portion (FIG. 12(C)). Therefore, the through-hole conductor of the embodiment bends at the boundary of the first opening portion and the third opening portion and at the boundary of the second opening portion and the third opening portion. When the number of bent portions is compared between the through-hole conductor shown in FIG. 12(B) and the through-hole conductor of the embodiment, the number in the through-hole conductor of the embodiment is greater than that in the through-hole conductor shown in FIG. 12(B). Accordingly, in the through-hole conductor of the embodiment, stress exerted on a through-hole conductor is dispersed. As a result, cracking occurs less often in the through-hole conductor of the embodiment than in the through-hole conductor shown in FIG. 12(B).

Multilayer printed wiring board 10 in FIG. 6 has buildup layers on both surfaces of printed wiring board 30. Buildup layers are formed with interlayer resin insulation layer 50, conductive circuit 58 on interlayer resin insulation layer 50, and via conductor 60 which penetrates through interlayer resin insulation layer 50. Via conductor 60 connects conductive circuit 58 on interlayer resin insulation layer 50 with conductive circuit 34 or 342 of the printed wiring board or with through-hole conductor 36. Multilayer printed wiring board 10 shown in FIG. 6 has a buildup layer on each side. Multilayer printed wiring board 10 shown in FIG. 6 has solder-resist layers 70 on the buildup layers, and via conductors 60 and conductive circuits 58 of the buildup layers are exposed through openings 71 in solder-resist layers 70. Bumps (76U, 76D) are formed in those exposed portions.

In multilayer printed wiring board 10 of the embodiment, a through-hole conductor tapers from the first surface of the core substrate toward the filler resin, and tapers from the second surface of the core substrate toward the filler resin. Accordingly, the areas at end portions of the through-hole conductor are enlarged. As a result, since it is easy to form via conductors 60 on (end portions of) the through-hole conductor, productivity is improved. Also, connection reliability increases between a through-hole conductor and via conductors formed directly on the through-hole conductor.

Since a through-hole conductor according to the embodiment has various effects as described above, stress exerted on a through-hole conductor and on a via conductor formed directly on the through-hole conductor is reduced. As a result, connection reliability increases between a through-hole conductor and a via conductor formed directly on the through-hole conductor.

Metal layer 20 of printed wiring board 30 is preferred to be used as power supply or ground.

In the embodiment, a through-hole conductor is formed by filling plating in a penetrating hole for a through-hole conductor which is made up of a first opening portion, a second opening portion and a third opening portion. Accordingly, even if the metal layer is thin (thickness: 15˜150 μm), cracking is prevented from occurring at an interface between metal layer 20 and first resin insulation layer 24, second resin insulation layer 25 or filler resin 27. In addition, surfaces of metal layer 20 may be roughened. Adhesiveness between metal layer 20 and first resin insulation layer 24, second resin insulation layer 25 or filler resin 27 is improved.

The first resin insulation layer and the second resin insulation layer are preferred to contain reinforcing material (core material). As for the reinforcing material, glass cloth, aramid fiber and the like may be listed. The first resin insulation layer and the second resin insulation layer may contain reinforcing material and inorganic particles such as silica. Filler resin is preferred not to contain reinforcing material such as glass cloth and aramid fiber. Filler resin is preferred not to contain reinforcing material but to contain inorganic particles. When the first resin insulation layer and the second resin insulation layer contain reinforcing material (core material) and inorganic particles, their thermal expansion coefficient is closer to that of the metal layer. When resin filler contains inorganic particles, its thermal expansion coefficient is closer to that of the metal layer. Cracking seldom occurs in the first resin insulation layer, the second resin insulation layer or filler resin during heat cycles. Also, peeling is prevented between the metal layer and the first resin insulation layer, the second resin insulation layer or filler resin during heat cycles.

Filler resin is formed by resin that has flowed from at least either the first resin insulation layer or the second resin insulation layer into an opening in the metal layer. In such a case, it is preferred that resin and inorganic particles from at least either the first resin insulation layer or the second resin insulation layer flow into an opening in the metal layer.

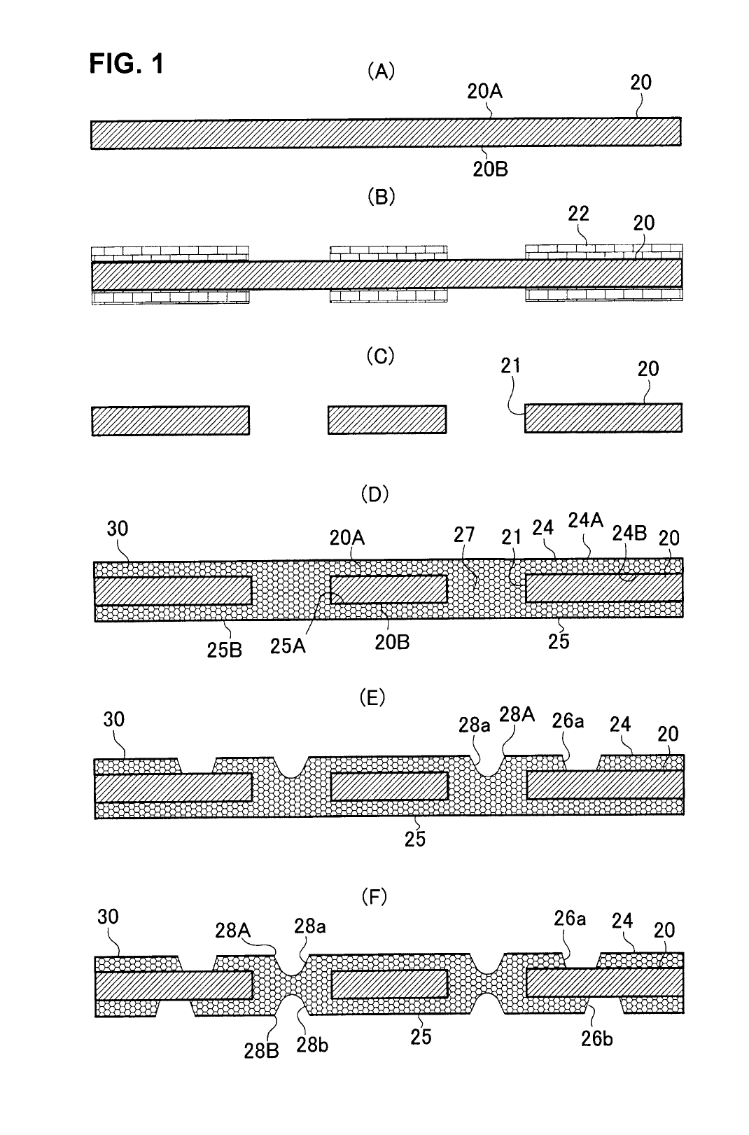

FIGS. 1 through 6 show a method for manufacturing multilayer printed wiring board 10. Metal layer (metal sheet) 20 is prepared (FIG. 1(A)). The thickness of the metal layer is preferred to be in the range of 15 μm to 150 μm. When the thickness of the metal layer is in the above range, heat is radiated through the metal layer, and malfunctions seldom occur in electronic components such as a memory mounted on printed wiring board 30 or on multilayer printed wiring board 10. Also, in printed wiring board 30 and multilayer printed wiring board 10 according to the embodiment, the portion of a through-hole conductor that penetrates through the metal layer is narrow. Although cracking tends to occur in a narrow portion, since the metal layer is thin, the narrow portion of a through-hole conductor is short in printed wiring board 30 and multilayer printed wiring board 10 according to the embodiment. As a result, reliability of the through-hole conductor increases. Since printed wiring board 30 and multilayer printed wiring board 10 of the embodiment have excellent heat radiation, the amount of deformation decreases in printed wiring board 30 and multilayer printed wiring board 10. Therefore, even though a through-hole conductor in printed wiring board 30 and multilayer printed wiring board 10 of the embodiment has a narrow portion, malfunctioning such as cracking seldom occurs in the through-hole conductor.

The metal layer (metal sheet) has first surface (20A) and second surface (20B) opposite the first surface. Metals such as copper, nickel, aluminum, titanium and zinc are listed as the material for metal foil and metal sheet. Also, alloys of metals selected from those metals are used as the material. As for specific examples, alloy 42, kovar, bronze and copper foil are listed. Here, the metal sheet may be a single layer or a laminate of multiple metal layers. An example of a laminate is a triple-layer laminate formed with metal foil mainly containing nickel sandwiched by metal foils mainly containing copper. The thickness of each layer and the combination of the materials are not limited specifically. Among those, copper is preferred as a material for the metal layer; copper foil is especially preferable. Since conductive circuits of the printed wiring board are made of metal mainly containing copper, problems related to electrical characteristics seldom occur. Also, when the metal layer is made of copper foil, openings and roughened surfaces are easy to form.

(2) Etching resist 22 is formed on the first and second surfaces of metal layer 20 (FIG. 1(B)).

(3) A portion of the metal layer exposed from etching resist 22 is removed by etching. Opening 21 is formed in metal layer 20. After that, the etching resist is removed. The metal layer with opening 21 is completed (FIG. 1(C)). The size of opening 21 is 150 μm˜260 μm. The smallest diameter of a penetrating hole for a through-hole conductor divided by the diameter of opening 21 is 0.12˜0.7. Diameter (X1) of first opening (28A) of the first opening portion divided by the smallest diameter (X5) of a penetrating hole for a through-hole conductor as well as diameter (X2) of second opening (28B) of the second opening portion divided by the smallest diameter (X5) of the penetrating hole for a through-hole conductor is 1.2˜1.75. The smallest diameter of a penetrating hole is (X5) as shown in FIGS. 13(A) and (C). (X1) and (X2) are shown in FIGS. 13(A) and (C). Other than etching, a laser or a drill may also be used for forming opening 21. The surfaces of the metal layer may be roughened. The first and second surfaces of the metal layer are roughened. The inner wall of the opening in the metal layer is also preferred to be roughened.

(4) Insulation layers are laminated on both surfaces of the metal layer. The insulation layers are preferred to contain a core material and B-stage resin. The core material is glass cloth, aramid fiber or the like. Resin is epoxy, polyimide or the like. In addition, insulation layers are preferred to contain inorganic particles. Inorganic particles are silica, alumina or the like. The thickness of insulation layers is 20 μm to 200 μm. The metal layer and insulation layers sandwiching the metal layer are thermal pressed. The metal layer and the insulation layers are integrated. During that time, resin contained in the insulation layers seeps into an opening in the metal layer and fills the opening in the metal layer with the resin contained in the insulation layers. If the insulation layers contain inorganic particles, resin and inorganic particles contained in the insulation layers seep into an opening in the metal layer. Opening 21 in the metal layer is filled with resin and inorganic particles contained in the insulation layers. Then, resin in the insulation layers and resin in the opening are cured. Filler resin 27 is formed in opening 21. Filler resin is preferred to be formed with resin and inorganic particles. In addition, on the first surface of the metal layer, a first resin insulation layer having an upper surface and a lower surface opposite the upper surface is formed. The first surface of the metal layer faces the lower surface of the first resin insulation layer. On the second surface of the metal layer, a second resin insulation layer having a main surface and a secondary surface opposite the main surface is formed. The second surface of the metal layer faces the secondary surface of the first resin insulation layer (FIG. 1(D)).

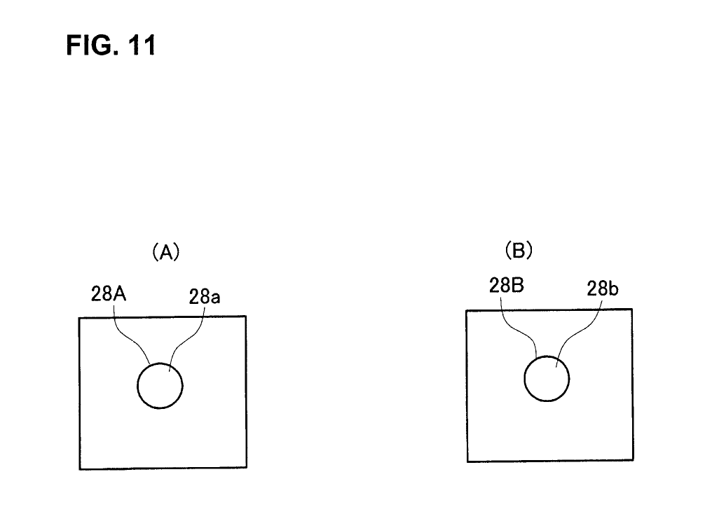

(5) A laser is irradiated from the upper-surface side of the first resin insulation layer. First opening portion (28a) is formed in the first resin insulation layer as part of a penetrating hole for a through-hole conductor. Moreover, via-conductor opening (26a) reaching the metal layer is formed in the first resin insulation layer (FIG. 1(E)). Here, first opening portion (28a) has first opening (28A) on the upper surface of the first resin insulation layer, and tapers from the upper surface toward the lower surface. The first opening portion becomes narrower from the upper surface of the first resin insulation layer toward the lower surface. By using a laser having intense energy in the central portion, a taper-shaped first opening portion is formed. FIG. 11(A) shows the upper surface of the first resin insulation layer, and the first opening portion has first opening (28A) on the upper surface.

(6) A laser is irradiated from the main-surface side of the second resin insulation layer. Second opening portion (28b) is formed in the second resin insulation layer as part of a penetrating hole for a through-hole conductor. In addition, via-conductor opening (26b) reaching the metal layer is formed in the second resin insulation layer (FIG. 1(F)). Here, second opening portion (28b) has second opening (28B) on the main surface of the second resin insulation layer, and tapers from the main surface toward the secondary surface. The second opening portion becomes narrower from the main surface of the second resin insulation layer toward the secondary surface. By using a laser having intense energy in the central portion, a taper-shaped second opening portion is formed. FIG. 11(B) shows the main surface of the second resin insulation layer, and the second opening portion has second opening (28B) on the main surface.

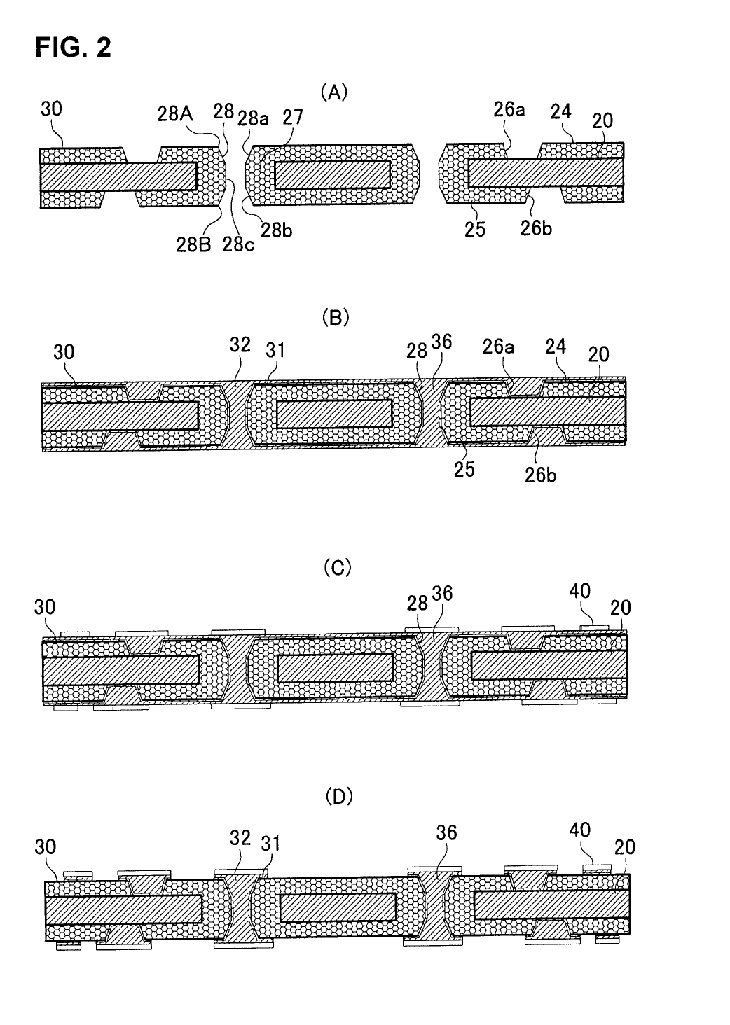

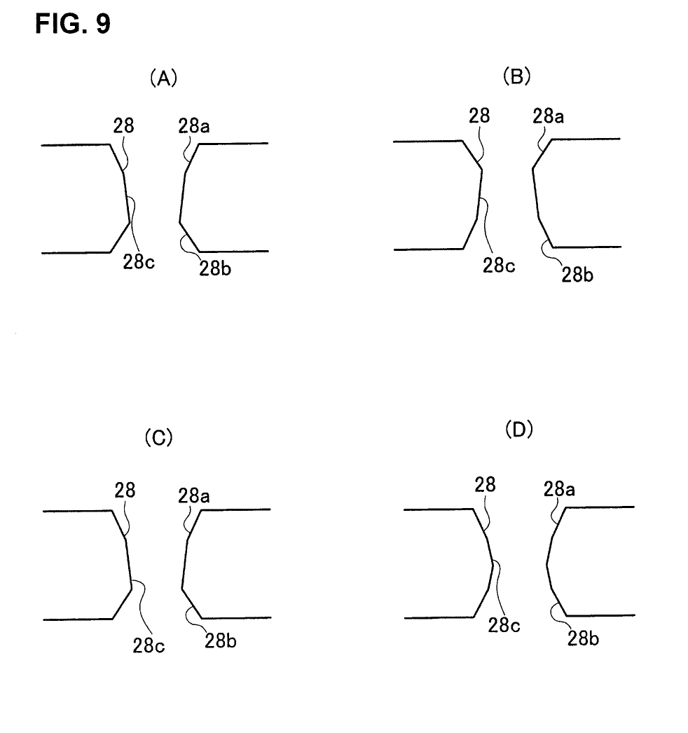

(7) From the upper-surface side of the first resin insulation layer or from the main-surface side of the second resin insulation layer, third opening portion (28c) is formed in filler resin by a drill so as to penetrate through filler resin 27. Third opening portion 28c connects first opening portion (28a) and second opening portion (28b). Penetrating hole 28 for a through-hole conductor is completed (FIG. 2(A)). Penetrating hole 28 for a through-hole conductor is formed with a first opening portion, a second opening portion and a third opening portion. The diameter of third opening portion (28c) is substantially constant. Third opening portion (28c) is formed by using a drill with a narrowed tip. When third opening portion (28c) is formed from the upper-surface side of the first resin insulation layer using a drill with a narrowed tip, third opening portion (28c) is formed to taper from the upper-surface side toward the main-surface side (FIG. 9(A)). When third opening portion (28c) is formed from the main-surface side of the second resin insulation layer using a drill with a narrowed tip, third opening portion (28c) is formed to taper from the main-surface side toward the upper-surface side (FIG. 9(B)).

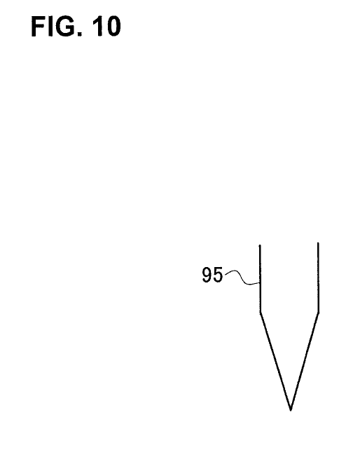

First, a penetrating hole is formed in the filler resin from the upper-surface side of the first resin insulation layer using a drill with a narrowed tip (FIG. 9(C)). Then, a penetrating hole is formed in the filler resin from the main-surface side of the second resin insulation layer using a drill with a narrowed tip (FIG. 9(D)). Third opening portion (28c) shown in FIG. 9(D) becomes narrower toward a predetermined point between the first surface and the second surface of the metal layer, and then third opening portion (28c) becomes wider from the predetermined point toward the second surface of the metal layer. FIG. 10 shows an example of the shape of drill 95 for forming third opening portion (28c) shown in FIGS. 9(A), (B) and (D).

First and second opening portions are formed by a laser and the third opening portion is formed by a drill. Accordingly, the inner wall of the penetrating hole bends at the boundary of the first opening portion and the third opening portion. Also, the inner wall of the penetrating hole bends at the boundary of the second opening portion and the third opening portion. The direction to bend is in the direction of the cross section of the penetrating hole (direction along axis Z). Therefore, the diameter of the third opening portion is substantially constant.

(8) Seed layer 31 is formed on the inner wall of the penetrating hole, on the surface of the first resin insulation layer and on the surface of the second resin insulation layer. The seed layer is electroless plated film or sputtered film. Copper is preferred as a seed layer. Using seed layer 31 as an electrode, electrolytic plating is performed. Electrolytic plated film 32 is formed on the seed layer. The penetrating hole is filled with electrolytic plated film. Through-hole conductor 36, which is made of a seed layer and electrolytic plated film 32 on the seed layer, is formed. When a resin insulation layer has a via-conductor opening, the via-conductor opening is filled with electrolytic plated film (FIG. 2(B)). In the present embodiment, the diameter of penetrating hole 28 for a through-hole conductor is greater in first opening (28A) and second opening (28B) (end portions), and narrower in the center of the core substrate. Therefore, since penetrating hole 28 is filled with plating starting from the center of the penetrating hole, a void tends not to remain in the through-hole conductor. As a result, reliability increases in the through-hole conductor of the embodiment.

(9) Etching resist 40 with a predetermined pattern is formed on electrolytic plated film 32 on surfaces of the substrate (FIG. 2(C)).

(10) Seed layer 31 and electrolytic plated film 32 exposed through etching resist 40 are removed (FIG. 2(D)).

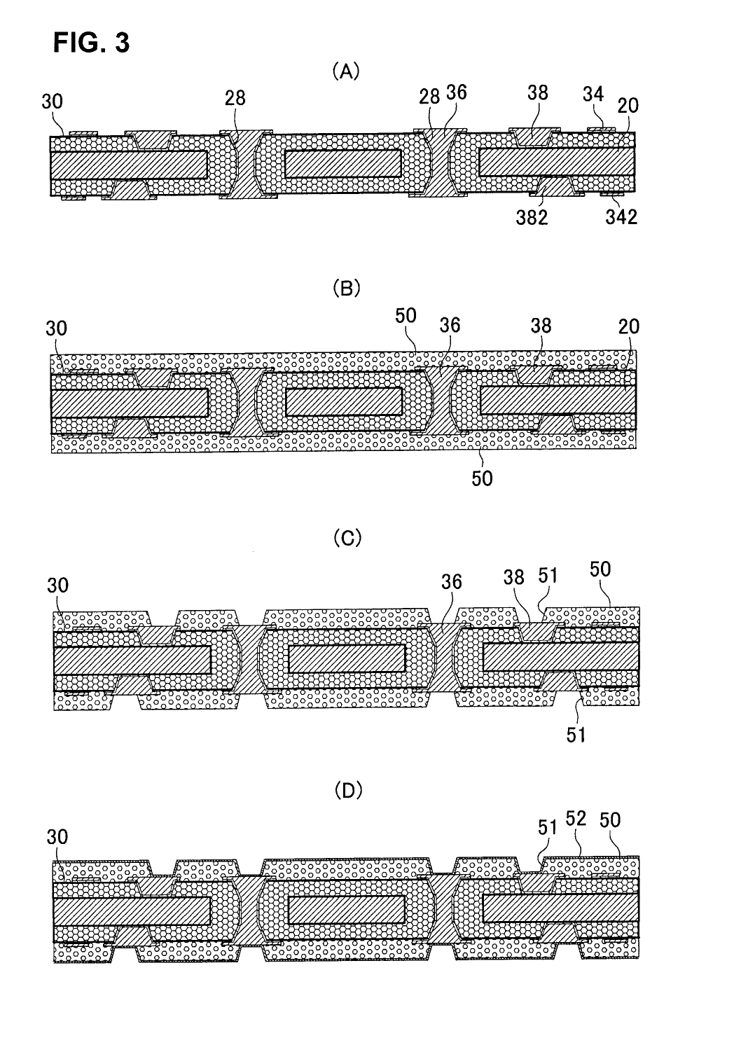

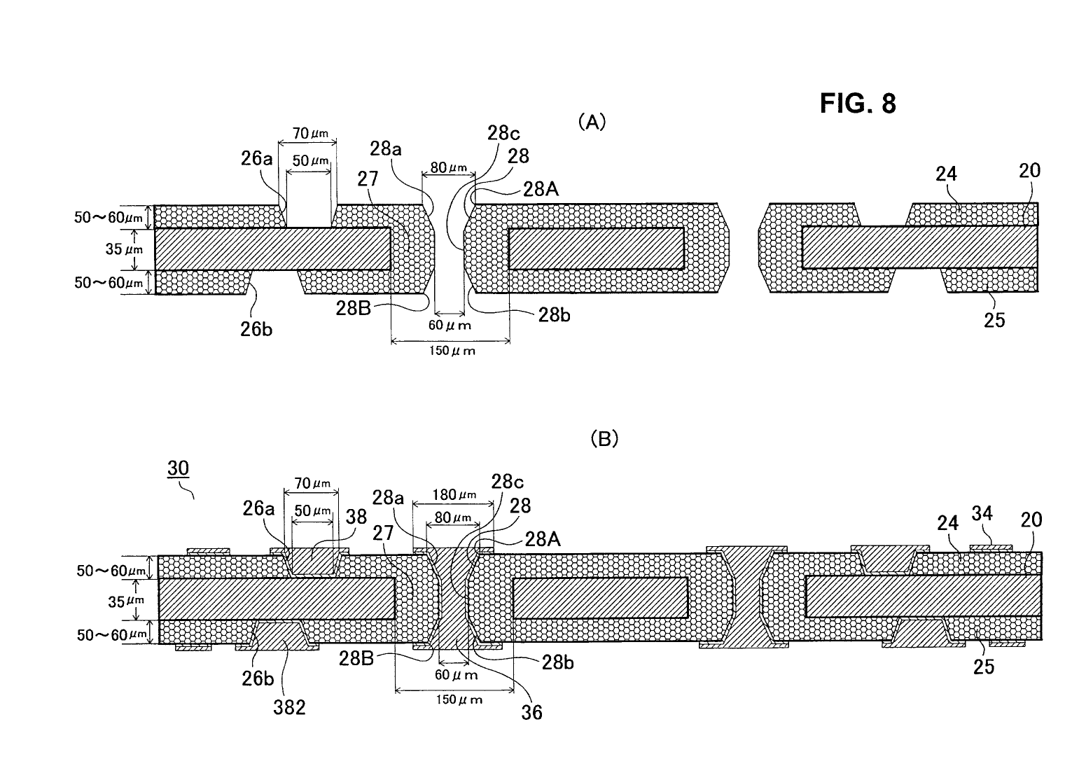

(11) Etching resist 40 is removed. Conductive circuit 34 is formed on the upper surface of the first resin insulation layer. Conductive circuit 342 is formed on the main surface of the second resin insulation layer. Conductive circuit 34 and conductive circuit 342 are connected by through-hole conductor 36. When the resin insulation layers have via-conductor openings, via conductors (38, 382) are formed in their respective openings. Via conductors connect the metal layer and conductive circuits (34, 342). When resin insulation layers have via conductors, the metal layer is preferred to function as ground or power supply. Printed wiring board 30 is completed (FIG. 3(A)). The core substrate is formed with a metal layer, a first resin insulation layer, a second resin insulation layer, filler resin and a through-hole conductor. The core substrate has a first surface and a second surface opposite the first surface. The first surface of the core substrate is on the same plane as the upper surface of the first resin insulation layer, and the second surface of the core substrate is on the same plane as the main surface of the second resin insulation layer. FIG. 8(B) is a magnified view of the core substrate. A penetrating hole in the embodiment is formed with first opening portion (28a) which tapers from the first surface of the core substrate toward the second surface, second opening portion (28b) which tapers from the second surface of the core substrate toward the first surface, and third opening portion (28c) in a straight shape. Then, by filling penetrating hole 28 with plating, through-hole conductor 36 is formed.

### Modified Examples of the Embodiment

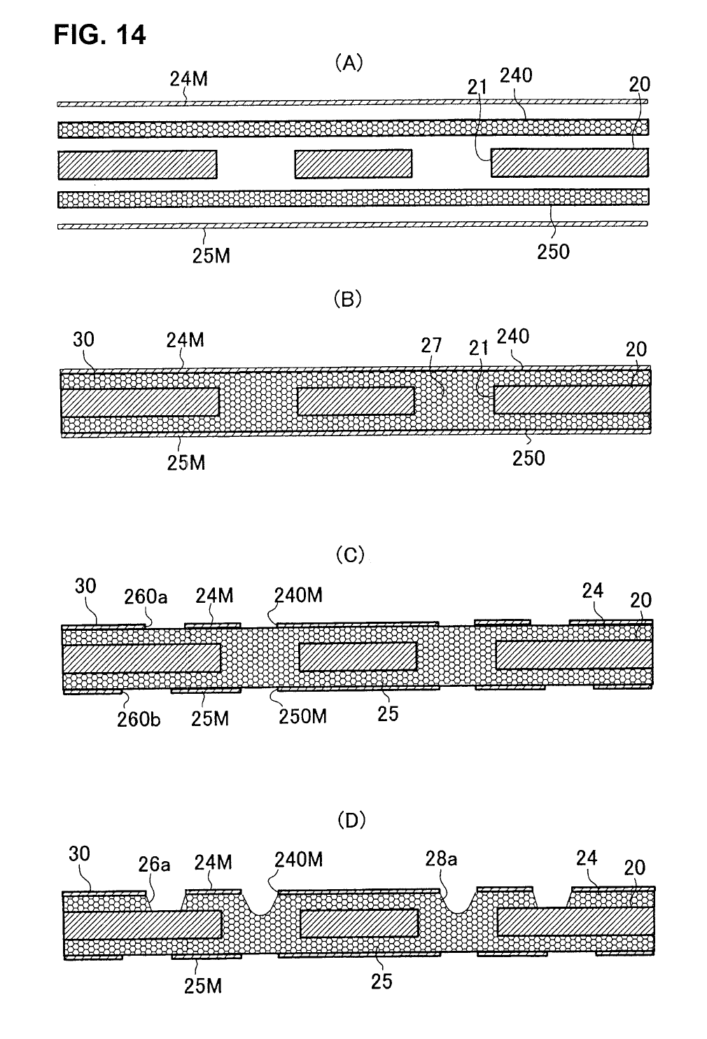

In a modified example of the embodiment, metal foil is further laminated on the insulation layers in step (4) of the embodiment (FIG. 14(A)). As for the metal foil, copper foil with the thickness of 3 μm to 15 μm is preferred. Metal layer 20, insulation layers (240, 250) sandwiching the metal layer, metal foil (24M) on insulation layer 240 and metal foil (25M) on insulation layer 250 are integrated through thermal pressing (FIG. 14(B)). Openings (240M, 250M) are formed in metal foils (24M, 25M) in portions positioned on filler resin 27 (FIG. 14(C)).

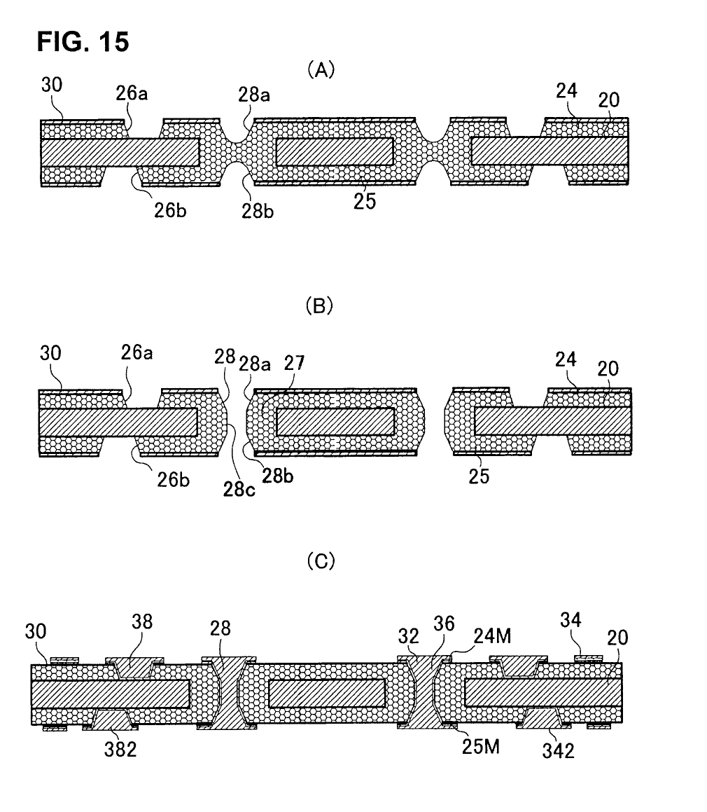

Next, a laser is irradiated at first resin insulation layer 24 through opening (240M) in the metal foil, and first opening portion (28a) is formed in the first resin insulation layer (FIG. 14(D)). A laser is irradiated at second resin insulation layer 25 through opening (250M) in the metal foil, and second opening portion (28b) is formed in the second resin insulation layer (FIG. 15(A)). Then, the same as in the first embodiment, third opening portion (28c) connecting the first opening portion and the second opening portion is formed in filler resin 27 by a drill (FIG. 15(B)).

Conductive circuits (34, 342) and a through-hole conductor are formed in substantially the same manner as those in the embodiment. In the modified example of the embodiment, the seed layer, electrolytic plated film and metal foils (24M, 25M) exposed from the etching resist are removed when conductive circuits are formed. Printed wiring board 30 is completed (FIG. 15(C)).

In the modified example of the embodiment, conductive circuits (34, 342) are formed with metal foil, a seed layer on the metal foil and electrolytic plated film on the seed layer, and a through-hole conductor is formed with the seed layer and electrolytic plated film on the seed layer. Through-hole lands formed around the through-hole conductor are formed with metal foil, the seed layer on the metal foil and electrolytic plated film on the seed layer.

### Forming Buildup Layers

Interlayer resin insulation layers (brand name: ABF-45SH made by Ajinomoto) 50 are formed on both surfaces of printed wiring board 30 (see FIG. 3(B)).

Next, using a CO2 gas laser, via-conductor openings 51 with a diameter of 40 μm˜80 μm are formed in interlayer resin insulation layers 50 (see FIG. 3(C)).

Electroless plated film 52 is formed on the surface layers of interlayer resin insulation layers 50 and on the inner walls of via-conductor openings (FIG. 3(D)).

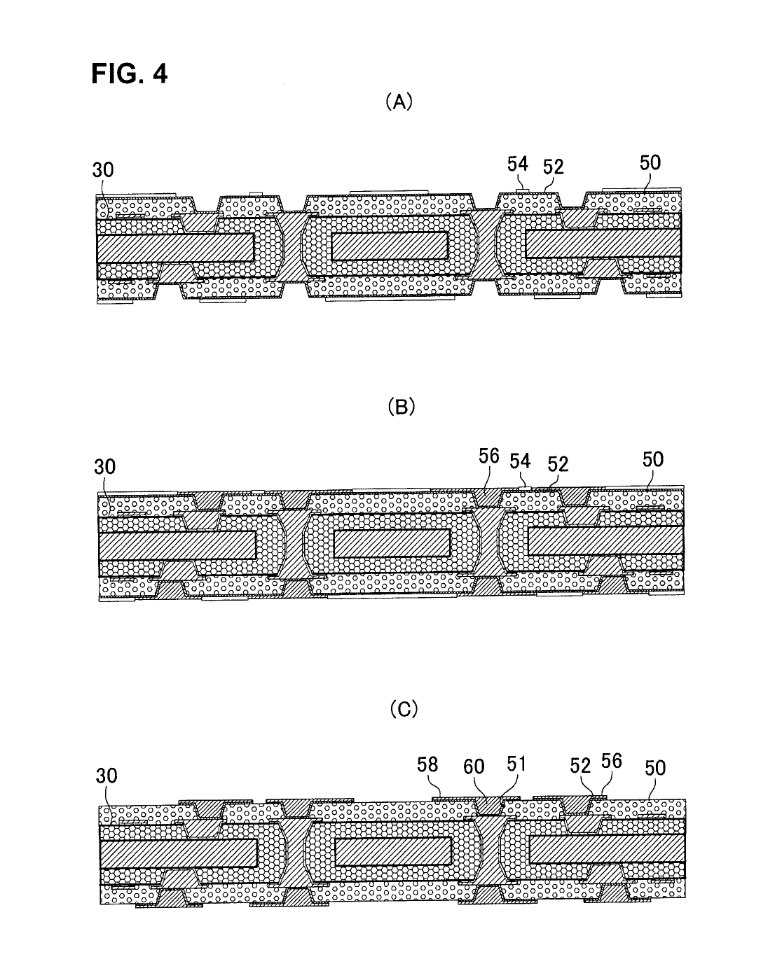

Plating resist 54 is formed on electroless plated film 52 (FIG. 4(A)).

Next, electrolytic plated film 56 is formed on the electroless plated film (see FIG. 4(B)).

Plating resist 54 is removed. Then, electroless plated film 52 between portions of electrolytic plated film 56 is removed. Conductive circuits 58 and via conductors 60 made of electroless plated film 52 and electrolytic plated film 56 are formed (FIG. 4(C)).

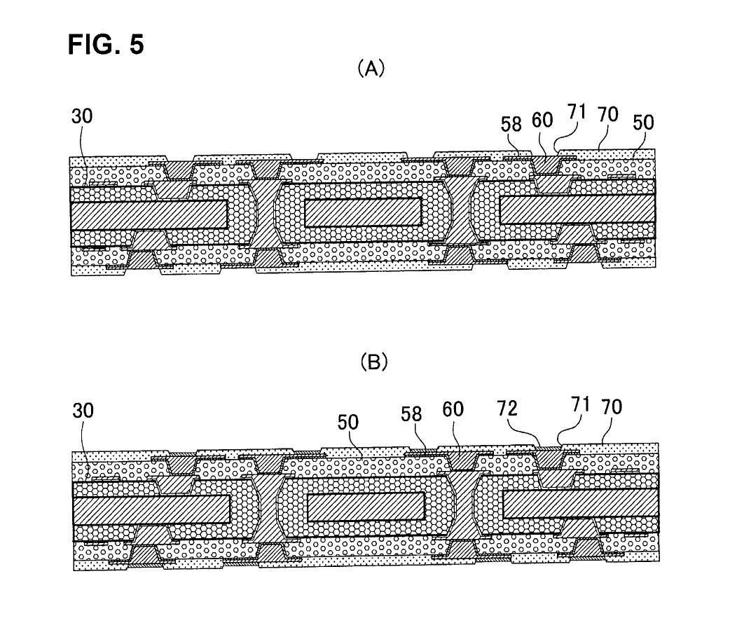

Next, interlayer resin insulation layers, conductive circuits and solder-resist layers 70 having openings 71 on via conductors are formed (FIG. 5(A)). Conductive portions exposed through the openings in the solder resist function as pads.

Sn film 72 is formed on the pads (FIG. 5(B)).

Then, by loading solder balls in openings 71 and conducting a reflow, solder bumps (76U, 76D) are formed on the pads. Multilayer printed wiring board 10 is completed (FIG. 6).

IC chip 90 is mounted through solder bumps (76U) on multilayer printed wiring board 10 (FIG. 7).

### Example

(1) A copper foil with the thickness of 35 μm 20 is prepared (FIG. 1(A)). The copper foil has a first surface and a second surface opposite the first surface.

(2) Etching resist 22 is formed on the first surface and second surface of copper foil 20 (FIG. 1(B)).

(3) The copper foil exposed from etching resist 22 is removed by etching. Opening 21 is formed in copper foil 20. Then, the etching resist is removed. A metal layer having opening 21 is completed (FIG. 1(C)). The size of opening 21 is 150 μm (FIG. 8(A)). The minimum width (diameter) of a penetrating hole for a through-hole conductor formed in opening 21 is 60 μm (FIG. 8(A)). The minimum diameter of a penetrating hole for a through-hole conductor formed in opening 21 corresponds to (X5). The diameters of the first opening and the second opening are 80 μm. The first surface and the second surface of the copper foil and the inner wall of opening 21 are roughened by Cz treatment (made by Mec Company Ltd.).

(4) Commercially available prepreg sheets (60 μm) (240, 250) are laminated on both surfaces of the metal layer. Such prepreg contains silica particles and glass cloth (FIG. 14(A)).

(5) On the outer side of the prepreg sheets, copper foils (24M, 25M) with the thickness of 5 μm are laminated (FIG. 14(A)).

(6) Copper foil 20, prepreg sheets (240, 250) sandwiching the copper foil, and copper foils (24M, 25M) on the outer side of the prepreg sheets are integrated through thermal pressing. During that time, resin and silica particles contained in the prepreg fill opening portion 21 in copper foil 20. Then, by curing the resin of the prepreg and the resin inside opening 21, first resin insulation layer 24, second resin insulation layer 25 and filler resin 27 are formed (FIG. 14(B)).

(7) Openings (240M, 250M) are formed in copper foils (24M, 25M) (FIG. 14(C)). Openings (240M, 250M) are formed in positions facing filler resin. Openings (260a, 260b) are formed in copper foils in positions to form via-conductor openings. The diameters of openings (240M, 250M) are 80 μm (FIG. 8A)). Copper foils (24M, 25M) are not shown in FIG. 8.

(8) A CO2 laser is irradiated at the first resin insulation layer through opening (240M) in copper foil (24M) from the upper-surface side of the first resin insulation layer. First opening portion (28a) is formed in the first resin insulation layer as part of a penetrating hole for a through-hole conductor (FIG. 14(D)). The energy of the laser for forming first opening portion (28a) is stronger in the center than in the periphery. Therefore, first opening portion (28a) becomes gradually narrower from the upper surface of the first resin insulation layer toward the lower surface. First opening portion (28a) has first opening (28A) on the upper surface of the first resin insulation layer. The diameter of the first opening is 80 μm, and the diameter of first opening portion (28a) at the interface between filler resin and the first resin insulation layer is 40 μm. A via-conductor opening reaching the metal layer is formed in the first resin insulation layer. The top diameter of the via-conductor opening is 70 μm and the bottom diameter is 50 μm (FIG. 8(A)).

(9) A CO2 laser is irradiated at the second resin insulation layer through opening (250M) in copper foil (25M) from the main-surface side of the second resin insulation layer. Second opening portion (28b) is formed in the second resin insulation layer as part of a penetrating hole for a through-hole conductor (FIG. 15(A)). The energy of the laser for forming second opening portion (28b) is stronger in the center than in the periphery. Therefore, second opening portion (28b) becomes gradually narrower from the main surface of the second resin insulation layer toward the secondary surface. Second opening portion (28b) has second opening (28B) on the main surface of the second resin insulation layer. The diameter of the second opening is 80 μm, and the diameter of second opening portion (28b) at the interface between filler resin and the second resin insulation layer is 40 μm. A via-conductor opening reaching the metal layer is formed in the second resin insulation layer. The top diameter of the via-conductor opening is 70 μm and the bottom diameter is 50 μm (FIG. 8(A)).

(10) Third opening portion (28c), which penetrates through filler resin 27, is formed by using a drill (diameter 60 μm) from the upper-surface side of the first resin insulation layer. Such a drill may be obtained from Kanamori Drill Mfg. Co., Ltd. or the like. The third opening portion has a diameter of 60 μm and is shaped straight (FIG. 8(A)). Third opening portion 28c connects first opening portion (28a) and second opening portion (28b). Penetrating hole 28 for a through-hole conductor is completed (FIG. 15(B)). (X1) and (X2) of a penetrating hole in the example are 80 μm, and (X3), (X4) and (X5) are 60 μm. The inner wall of the penetrating hole bends in the direction of the cross section at the boundary of the first opening portion and the third opening portion and at the boundary of the second opening portion and the third opening portion.

(11) Using a commercially available electroless copper plating solution, electroless copper-plated film is formed on the inner wall of a penetrating hole, on the copper foil formed on the first resin insulation layer, on the copper foil formed on the second resin insulation layer, on the inner wall of a via-conductor opening in the first resin insulation layer, and on the inner wall of a via-conductor opening in the second resin insulation layer. Using a commercially available electrolytic copper plating solution, electrolytic copper-plated film 32 is formed on the electroless copper-plated film. The penetrating hole is filled with electrolytic copper-plated film. In the penetrating hole, through-hole conductor 36 made up of electroless copper-plated film and electrolytic copper-plated film 32 on the electroless copper-plated film is formed. Also, via-conductor openings formed in the resin insulation layers are filled with electrolytic plated film. Etching resist with a predetermined pattern is formed on electrolytic plated-film 32 on the surfaces of the substrate.

Electrolytic copper-plated film 32, electroless copper-plated film and copper foil exposed from the etching resist are removed. The etching resist is removed. Conductive circuit 34 is formed on the upper surface of the first resin insulation layer. Conductive circuit 342 is formed on the main surface of the second resin insulation layer. Conductive circuit 34 and conductive circuit 342 are connected by through-hole conductor 36. Via conductors (38, 382) are formed in via-conductor openings in the resin insulation layers. Via conductors connect the metal layer and conductive circuits (34, 342). The metal layer functions as ground. Printed wiring board 30 is completed (FIG. 15(C)).

(12) Interlayer resin insulation layers (brand name: ABF-45SH, made by Ajinomoto) 50 are formed on both surfaces of printed wiring board 30 (see FIG. 3(B)).

(13) Next, using a CO2 gas laser, via-conductor openings 51 with diameters of 60 μm are formed in interlayer resin insulation layers 50 (see FIG. 3(C)).

(14) Using a commercially available electroless-copper plating solution, electroless copper-plated film 52 is formed on the surface layers of interlayer resin insulation layers 50 and on the inner walls of via-conductor openings (FIG. 3(D)).

(15) Commercially available plating resist 54 is formed on electroless copper-plated film 52 (FIG. 4(A)).

(16) Next, electrolytic copper-plated film 56 is formed on the electroless plated film (FIG. 4(B)).

(17) Plating resist 54 is removed. Then, electroless plated film 52 between portions of electrolytic copper-plated film 56 is removed. Conductive circuits 58 and via conductors 60 made up of electroless plated film 52 and electrolytic plated film 56 are formed (FIG. 4(C)).

(18) Next, interlayer resin insulation layers, conductive circuits and solder-resist layers 70 having openings 71 on via conductors are formed (FIG. 5(A)). The conductive portions exposed through the solder-resist openings function as pads. The solder-resist layers are formed using commercially available material.

(19) Sn film 72 is formed on the pads (FIG. 5(B)).

(20) Then, by loading solder balls in openings 71, and by conducting a reflow, solder bumps (76U, 76D) are formed on the first-surface side (upper surface) of pads. Multilayer printed wiring board 10 is completed (FIG. 6).

A printed wiring board according to the first aspect of the present invention has the following: a metal layer with an opening and having a first surface and a second surface; a filler resin filled in the opening of the metal layer; a first resin insulation layer having an upper surface and a lower surface and formed on the first surface of the metal layer so that the lower surface faces the first surface of the metal layer; a second resin insulation layer having a main surface and a secondary surface and formed on the second surface of the metal layer so that the secondary surface faces the second surface of the metal layer; a first conductive circuit formed on the upper surface of the first resin insulation layer; a second conductive circuit formed on the main surface of the second resin insulation layer; and a through-hole conductor formed in a penetrating hole that penetrates through the first resin insulation layer, the filler resin and the second resin insulation layer and connecting the first conductive circuit and the second conductive circuit. The penetrating hole is made up of a first opening portion formed in the first resin insulation layer, of a second opening portion formed in the second resin insulation layer, and of a third opening portion formed in the filler resin and connecting the first opening portion and the second opening portion, the first opening portion is made gradually narrower from the upper surface of the first resin insulation layer toward the filler resin, the second opening portion is made gradually narrower from the main surface of the second resin insulation layer toward the filler resin, and the diameter of the third opening portion is made substantially constant from the boundary of the first opening portion and the third opening portion to the boundary of the second opening portion and the third opening portion.

Obviously, numerous modifications and variations of the present invention are possible in light of the above teachings. It is therefore to be understood that within the scope of the appended claims, the invention may be practiced otherwise than as specifically described herein.

What is claimed is:

1. A printed wiring board, comprising:
a core substrate comprising a metal layer, a first resin insulation layer formed on a first surface of the metal layer and a second resin insulation layer formed on a second surface of the metal layer on an opposite side of the first surface of the metal layer;
a first conductive circuit formed on a surface of the first resin insulation layer of the core substrate;
a second conductive circuit formed on a surface of the second resin insulation layer of the core substrate; and
a through-hole conductor formed in a penetrating hole penetrating through the core substrate and connecting the first conductive circuit and the second conductive circuit,
wherein the metal layer has an opening portion filled with a filler resin, the penetrating hole formed through the core substrate has a first opening portion formed in the first resin insulation layer, a second opening portion formed in the second resin insulation layer and a third opening portion formed in the filler resin, the first opening portion becomes narrower from the surface of the first resin insulation layer toward the filler resin, the second opening portion becomes narrower from the surface of the second resin insulation layer toward the filler resin, and the third opening portion is connecting the first opening portion and the second opening portion.

2. The printed wiring board according to claim 1, wherein the third opening portion has a diameter which is substantially constant from a boundary of the first opening portion and the third opening portion to a boundary of the second opening portion and the third opening portion.

3. The printed wiring board according to claim 1, wherein the metal layer has a thickness which is set in a range of 15 μm to 150 μm.

4. The printed wiring board according to claim 1, wherein at least one of the first and second surfaces of the metal layer has a roughened surface.

5. The printed wiring board according to claim 1, wherein at least one of the first resin insulation layer and the second resin insulation layer includes inorganic particles and a core material.

6. The printed wiring board according to claim 1, further comprising a via conductor formed in the first resin insulation layer and connected to the metal layer in the core substrate.

7. The printed wiring board according to claim 1, further comprising:
a first via conductor formed in the first resin insulation layer and connected to the metal layer in the core substrate; and
a second via conductor formed in the second resin insulation layer and connected to the metal layer in the core substrate.

8. The printed wiring board according to claim 1, further comprising:
a first via conductor formed in the first resin insulation layer and connected to the metal layer in the core substrate; and
a second via conductor formed in the second resin insulation layer and connected to the metal layer in the core substrate,
wherein the metal layer, the first via conductor and the second via conductor form one of a power supply through via conductor and a ground through via conductor.

9. The printed wiring board according to claim 1, wherein the through-hole conductor comprises a plating filling the penetrating hole.

10. The printed wiring board according to claim 1, wherein the through-hole conductor comprises an electroless plated film formed along an inner surface of the penetrating hole and an electrolytic plating filling a space formed by the electroless plated film in the penetrating hole.

11. The printed wiring board according to claim 1, wherein the first resin insulation layer, the second resin insulation layer and the filler resin in the core substrate comprise a same resin.

12. The printed wiring board according to claim 1, wherein the first resin insulation layer, the second resin insulation layer and the filler resin in the core substrate form an integral resin structure comprising a resin.

13. The printed wiring board according to claim 1, wherein via conductors reaching the metal layer are formed in the first resin insulation layer and the second resin insulation layer, and the metal layer functions as a power supply or ground through via conductors.

14. A method for manufacturing a printed wiring board, comprising:
preparing a core substrate comprising a metal layer, a first resin insulation layer formed on a first surface of the metal layer and a second resin insulation layer formed on a second surface of the metal layer on an opposite side of the first surface of the metal layer,
forming a first conductive circuit on a surface of the first resin insulation layer of the core substrate;
forming a second conductive circuit on a surface of the second resin insulation layer of the core substrate; and
forming a through-hole conductor in a penetrating hole penetrating through the core substrate and connecting the first conductive circuit and the second conductive circuit,
wherein the preparing of the core substrate comprises filling an opening portion of the metal layer with a filler resin, forming a penetrating hole through the core substrate such that a first opening portion is formed in the first resin insulation layer, a second opening portion is formed in the second resin insulation layer and a third opening portion is formed in the filler resin, and the forming of the penetrating hole comprises forming the first opening portion such that the first opening portion becomes narrower from the surface of the first resin insulation layer toward the filler resin, forming the second opening portion such that the second opening portion becomes narrower from the surface of the second resin insulation layer toward the filler resin, and forming the third opening portion such that the third opening portion is connecting the first opening portion and the second opening portion.

15. The method for manufacturing a printed wiring board according to claim 14, wherein the forming of the third opening portion comprises forming a diameter of the third opening portion substantially constant from a boundary of the first opening portion and the third opening portion to a boundary of the second opening portion and the third opening portion.

16. The method for manufacturing a printed wiring board according to claim 14, wherein the metal layer has a thickness which is set in a range of 15 μm to 150 μm.

17. The method for manufacturing a printed wiring board according to claim 14, further comprising roughening at least one of the first and second surfaces of the metal layer.

18. The method for manufacturing a printed wiring board according to claim 14, further comprising forming a via conductor in the first resin insulation layer such that the via conductor is connected to the metal layer in the core substrate.

19. The method for manufacturing a printed wiring board according to claim 14, further comprising:
forming a first via conductor in the first resin insulation layer such that the first via conductor is connected to the metal layer in the core substrate; and
forming a second via conductor in the second resin insulation layer such that the second via conductor is connected to the metal layer in the core substrate,
wherein the metal layer, the first via conductor and the second via conductor form one of a power supply through via conductor and a ground through via conductor.

20. The method for manufacturing a printed wiring board according to claim 14, wherein the forming of the through-hole conductor comprises filling the penetrating hole with a plating material.
